(19) United States
(12) Patent Application Publication
(10) Pub. No.: US 2025/0126960 A1
(43) Pub. Date: Apr. 17, 2025

(54) COLOR AND INFRARED IMAGE SENSOR

(71) Applicant: ISORG, Limoges CEDEX 3 (FR)

(72) Inventors: Benjamin BOUTHINON, GRENOBLE (FR); Camille DUPOIRON, GRENOBLE (FR)

(21) Appl. No.: 18/685,451

(22) PCT Filed: Jun. 24, 2022
(86) PCT No.: PCT/EP2022/067340

§ 371 Date: Feb. 21, 2024

(30) Foreign Application Priority Data
Sep. 10, 2021 (FR) FR2109529

(51) Int. Cl. H10K 39/00; H10F 39/00; H10F 39/18; H10K 39/32

(52) U.S. Cl. CPC H10K 39/401; H10F 39/184; H10F 39/8053; H10F 39/8057; H10F 39/8063; H10K 39/32

(57) ABSTRACT

A color and infrared image sensor includes: a first level having infrared photodetectors formed therein; a second level, located above the first level, having visible photodetectors formed therein, which are laterally offset with respect to the infrared photodetectors; and a layer of microlenses comprising a specific microlens in front of each infrared photodetector.

### FIELD

The present disclosure concerns an electronic image sensor or imager.

### BACKGROUND

Image sensors are used in many fields, in particular in electronic devices, due to their miniaturization. Image sensors are present be it in man-machine interface applications or in image capture applications.

For certain applications, it is desirable to have an image sensor enabling to simultaneously acquire a color image and an infrared image. Such an image sensor is called color and infrared image sensor in the following description. An example of application of a color and infrared image sensor concerns the acquisition of an infrared image of an object having a structured infrared pattern projected thereon. The fields of use of such image sensors particularly are motors vehicles, drones, smart phones, robotics, and augmented and/or virtual reality systems.

### SUMMARY OF THE INVENTION

An embodiment overcomes all or part of the disadvantages of the previously-described color and infrared image sensors.

An embodiment provides a color and infrared image sensor comprising:
a first level having infrared photodetectors formed therein;

a second level, located above the first level, having visible photodetectors formed therein; and
a layer of microlenses comprising a specific microlens in front of each infrared photodetector, wherein the visible photodetectors are laterally offset with respect to the infrared photodetectors.

According to an embodiment, the sensor comprises, between the second level and the layer of microlenses, a layer of color filters comprising a specific color filter in front of each visible photodetector.

According to an embodiment, the color filters are laterally separated from one another by opaque walls.

According to an embodiment, the microlenses are laterally offset with respect to the color filters.

According to an embodiment, the visible photodetectors are arranged in a first array, and the infrared photodetectors are arranged in a second array of same resolution and of same pitch as the first array.

According to an embodiment, in top view, the center-to-center distance between any two neighboring visible and infrared photodetectors is substantially equal to half the pitch of the first and second arrays.

According to an embodiment, the sensor comprises an inorganic semiconductor substrate, for example, made of single-crystal silicon, inside and on top of which are formed circuits for reading from the visible and infrared photodetectors.

According to an embodiment, the infrared photodetectors are inorganic photodetectors formed in said semiconductor substrate and the visible photodetectors are organic photodetectors.

According to an embodiment, the infrared photodetectors are organic photodetectors formed above the semiconductor substrate and the visible photodetectors are organic photodetectors.

According to an embodiment, each visible photodetector has an active region separated from active areas of the other photodetectors by an opaque wall.

### BRIEF DESCRIPTION OF THE DRAWINGS

The foregoing and other features and advantages of the present invention will be discussed in detail in the following non-limiting description of specific embodiments in connection with the accompanying drawing, in which:

FIG. 1A is a cross-section view schematically showing an example of a color and infrared image sensor according to a first embodiment;

FIG. 1B is a partial simplified top view of the color and infrared image sensor of FIG. 1A;

FIG. 2 is a cross-section view schematically and partially showing an alternative embodiment of the sensor of FIGS. 1A and 1B;

FIG. 3 is a cross-section view schematically and partially showing another alternative embodiment of the sensor of FIGS. 1A and 1B; and

FIG. 4 is a cross-section view schematically showing an example of a color and infrared image sensor according to a second embodiment.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, what use is made of the image sensors described hereafter has not been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the terms “about”, “approximately”, “substantially”, and “in the order of” signify within 10%, preferably within 5%.

Further, it is here considered that the terms “insulating” and “conductive” respectively signify “electrically insulating” and “electrically conductive”. Further, unless specified otherwise, “in contact with” means “in mechanical contact with”. Further, the term “radiation of interest” designates the radiation which is desired to be captured or emitted by an optoelectronic device. As an example, the radiation of interest may comprise the visible spectrum and near infrared, that is, wavelengths in the range from 400 nm to 1,700 nm, more particularly from 400 nm to 700 nm for the visible spectrum and from 700 nm to 1,700 nm for near infrared. The transmittance of a layer to a radiation corresponds to the ratio of the intensity of the radiation coming out of the layer to the intensity of the radiation entering the layer, the rays of the incoming radiation being perpendicular to the layer. In the following description, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%.

A pixel of an image corresponds to the unit element of the image captured by an image sensor. When the optoelectronic device is a color image sensor, it generally comprises, for each image pixel of the color image to be acquired, at least three components which each acquire a light radiation substantially in a single color, that is, in a wavelength range lower than 100 nm (for example, red, green, and blue). Each component may comprise at least one photodetector.

It is here provided to form a color and infrared image sensor preferably comprising at least one organic semiconductor layer.

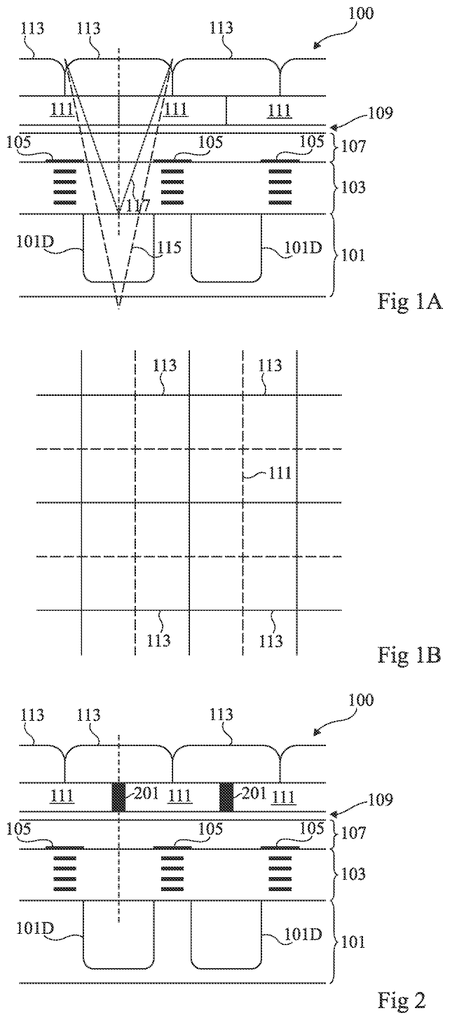

FIG. 1A is a partial and simplified cross-section view of an example of a color and infrared image sensor 100 according to an embodiment.

The image sensor 100 of FIG. 1A comprises an array of first photodetectors, also called infrared photodetectors, adapted to capturing an infrared image, and an array of second photodetectors, also called visible photodetectors, adapted to capturing a visible color image.

The infrared photodetectors are formed inside and on top of a semiconductor substrate 101, for example, inorganic, for example, made of silicon, for example, of single-crystal silicon. Each infrared photodetector comprises for example a doped region 101D of semiconductor substrate 101, defining a photodiode.

The visible photodetectors are, in this example, organic photodiodes formed above substrate 101. The organic photodiodes are for example more precisely based on a polymer material or based on small molecules. As a variant, photodiodes based on quantum dots or based on perovskite, that is, of a material having a perovskite-type structure, may be provided. In the shown example, the array of visible photodetectors is arranged above the array of infrared photodetectors. Sensor 100 is intended to be illuminated on its front side.

In the example of FIG. 1A, substrate 101 is coated with a stack 103 (called interconnection stack) of insulating layers, for example, made of silicon oxide, having metal tracks and metal interconnection vias formed therein. Portions of stack 103 comprising neither metal interconnection tracks nor vias, also called transmission windows, are arranged in front of the infrared photodetectors, to give way to part of the incident radiation towards the infrared photodetectors.

The visible photodetectors are arranged on the upper surface side of interconnection stack 103. The visible photodetectors each comprise a stack of a lower electrode 105, of an active region comprising a portion of organic semiconductor layer 107, and of an upper electrode (not shown). The active region for example, but not necessarily, comprises an electron injection layer on top of and in contact with a surface, for example, the lower surface, of organic semiconductor layer 107, and a hole injection layer on top of and in contact with the other surface, for example, the upper surface, of organic semiconductor layer 107. The active region may further comprise one or a plurality of electron blocking elements and/or one or a plurality of hole blocking layers (not shown). The active region for example, but not necessarily, forms a continuous layer extending over substantially the entire surface of sensor 100.

As an example, the lower electrodes 105 of the visible photodetectors (in contact with the lower surface of the active region) are differentiated to allow an individual reading of the visible photodetectors. The upper electrodes (not detailed in FIG. 1A) of the visible photodetectors (in contact with the upper surface of the active region) are for example common. As an example, the upper electrodes of the visible photodetectors form a continuous layer extending over substantially the entire surface of the active area of sensor 100, for example over a surface area slightly greater than that of the active area of sensor 100. The lower and upper electrodes are preferably at least partially transparent.

The array of visible photodetectors may be coated with one or a plurality of encapsulation layers 109, for example, insulating layers, particularly enabling to protect organic semiconductor material 107 against outside aggressions (humidity, oxidation, etc.).

Each visible photodetector is topped with a color filter 111, coating, in this example, encapsulation layer 109. Color filters 111 may correspond to blocks of colored resin. The lower electrodes 105 of the visible photodetectors are aligned with respect to color filters 111. Each color filter 111 is adapted to letting through a wavelength in the range from 700 nm to 1 mm, and, for at least some of color filters 111, to only letting through a wavelength range of visible light. For each pixel of the color image to be acquired, image sensor 100 may comprise a photodetector topped with a color filter 111 adapted to only letting through blue light, for example, in the wavelength range from 430 nm to 490 nm (defining a first sub-pixel called blue sub-pixel), a second photodetector topped with a color filter 111 adapted to only letting through green light, for example, in the wavelength range from 510 nm to 570 nm (defining a second sub-pixel called green sub-pixel), and a photodetector topped with a color filter 111 adapted to only letting through red light, for example, in the wavelength range from 600 nm to 720 nm (defining a third sub-pixel called red sub-pixel). As an example, color filters 111 are arranged in a Bayer array.

In this example, the layer of color filters 111 is topped with a layer of microlenses 113. More particular, the layer of microlenses 113 comprises a specific microlens 113 for each infrared photodetector. Each microlens 113 is a converging microlens adapted to focusing the incident light onto or into the photosensitive area of the associated infrared photodetector. In other words, the focal axis of each microlens 113 runs through the photosensitive area of the associated infrared photodetector, so that most of the incident rays are focused onto or into the photosensitive area of the infrared photodetector. As an example, in top view, for a pixel located in a central region of the sensor, the center of microlens 113 substantially coincides with the center of the photosensitive area of the underlying infrared photodetector. For pixels located in a peripheral region of the sensor, the center of each microlens 113 may be laterally offset with respect to the center of the photosensitive area of the corresponding infrared photodetector. This for example enables to compensate for optical effects caused by a main lens of the sensor (not shown in FIG. 2) located above the layer of microlenses 113 and by the fact that the sensor is substantially planar.

As an example, each microlens 113 focuses the light on the upper surface of the photosensitive area of the underlying infrared photodetector, and/or a focusing cone 115 of the light transmitted by each microlens 113 is flush with the metallizations of interconnection stack 103 surrounding, in top view, the photosensitive area of the underlying infrared photodetector. As a variant, the light may be focused according to another cone 117 at a point of the upper surface of substrate 101 located approximately vertically in line with the center of the overlying microlens 113.

The microlenses 113 of sensor 100 are dedicated to infrared photodetectors and the color filters 111 are dedicated to visible photodetectors.

FIG. 1B is a partial simplified top view of the color and infrared image sensor 100 of FIG. 1A.

In the example illustrated in FIG. 1B, the layer of microlenses 113 comprises an array of adjacent microlenses 113 of same resolution and of same pitch as the array of infrared photodetectors. For simplification, microlenses 113 have been symbolized, in FIG. 1B, by squares, it being understood that each microlens 113 may, in top view, have any shape, for example, circular.

Further, in this example, the layer of color filters 111 comprises an array of contiguous color filters 111 of same pitch and of same resolution as the array of visible photodetectors.

The array of visible photodetectors for example has the same pitch and the same resolution as the array of infrared photodetectors. In this case, the array of color filters 111 has, for example, substantially the same pitch and the same resolution as the array of microlenses 113. As an example, in top view, microlenses 113 substantially have the same dimensions as color filters 111.

According to an aspect of the embodiment of FIGS. 1A and 1B, the visible photodetectors are laterally offset with respect to the infrared photodetectors. In other words, each infrared photodetector is partially topped with at least four visible photodetectors and each visible photodetector extends partially over at least four infrared photodetectors.

As a result, in the embodiment of FIGS. 1A and 1B, microlenses 113 are laterally offset with respect to color filters 111. In other words, in top view, the centers of microlenses 113 are laterally offset with respect to the centers of color filters 111. Thus, each color filter 111 is partially topped with at least four microlenses 113 and each microlens 113 partially extends over at least four color filters 111.

As an example, color filters 111 are respectively centered on the underlying visible photodetectors, and are off-centered with respect to the underlying infrared photodetectors.

As an example, the visible photodetectors are laterally offset by one half array pitch with respect to the infrared photodetectors. In this case, microlenses 113 are laterally offset by one half pitch with respect to color filters 111.

Semiconductor substrate 101 may further comprise circuits for reading from the infrared and visible photodetectors. The readout circuits are for example formed in CMOS (“Complementary Metal Oxide Semiconductor”) technology. The interconnection stack 103 coating the upper surface of substrate 101 may in particular comprise metallizations electrically connecting at least one electrode 105 of each visible photodetector to the readout circuits formed inside and on top of substrate 101.

The active area of each visible photodetector corresponds to the area where most of the incident radiation is absorbed and converted into an electric signal by the photodetector and substantially corresponds to the portion of the active layer located between lower electrode 105 and the upper electrode of the photodetector, for example, vertically in line with electrode 105.

An advantage of the embodiment of FIGS. 1A and 1B is that, due to the offset between the infrared photodetectors and the visible photodetectors, the metallizations of the interconnection stack 103 coating semiconductor substrate 101, and in particular the interconnection metallizations enabling to electrically connect the electrodes 105 of the visible organic photodetectors to the readout circuits formed inside and on top of substrate 101, do not, or only partially, block the radiations transmitted to the infrared photodetectors.

FIG. 2 is a cross-section view schematically and partially showing an alternative embodiment of the sensor 100 of FIGS. 1A and 1B.

In this variant, opaque walls 201, for example, made of metal, laterally separate color filters 111 from one another to avoid optical crosstalk phenomena between the different visible sub-pixels.

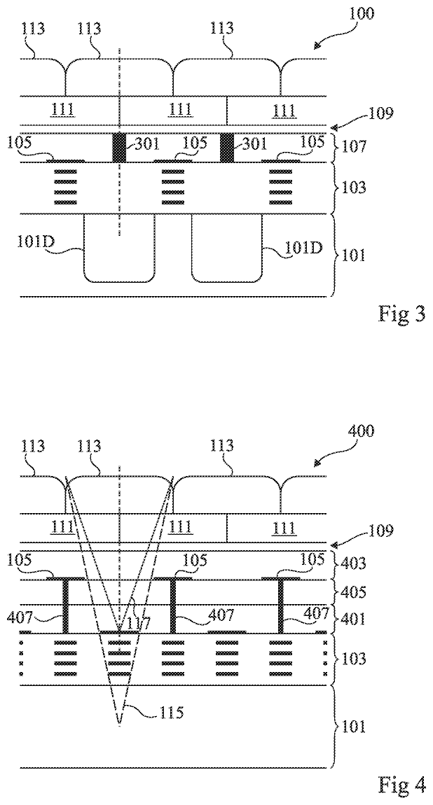

FIG. 3 is a cross-section view schematically and partially showing another alternative embodiment of the sensor 100 of FIGS. 1A and 1B.

In this variant, opaque walls 301, for example, made of metal or of resin, laterally separate the visible organic photodetectors from one another to avoid optical crosstalk phenomena between the different visible sub-pixels.

As an example, trenches are first etched through the active layer between the visible photodetectors, after which an opaque filling material, for example, metal, is deposited in the trenches to form opaque walls 301.

It should be noted that the variants of FIGS. 2 and 3 may be combined.

FIG. 4 is a cross-section view schematically showing an example of a color and infrared image sensor 400 according to a second embodiment.

The sensor 400 of FIG. 4 differs from the sensor 100 of FIGS. 1A and 1B mainly in that, in the embodiment of FIG. 4, sensor 400 comprises two active organic levels 401 and 403 stacked above semiconductor substrate 101. The infrared photodetectors are formed in first active organic level 401 from the upper surface of the semiconductor substrate 101, called lower level, and the visible photodetectors are formed in second organic active level 403 from the upper surface of semiconductor substrate 101, called upper level. As a variant, at least one of active levels 401 and 403 is based on quantum dots or on perovskites.

A dielectric layer 405 separates the two organic active levels 401 and 403. As an example, each organic active level 401, 403 has a thickness in the range from 50 nm to 2 μm, preferably from 400 nm to 600 nm or from 600 nm to 1,200 nm, and dielectric layer 405 has a thickness smaller than 3 μm, preferably smaller than 1 μm. Dielectric layer 405 is for example a resin layer. As a variant, dielectric layer 405 is made of silicon nitride or of silicon oxide.

In this example, lower semiconductor substrate 101 comprises no photodetectors, but only circuits for reading from the visible and infrared photodetectors. Conductive via 407, for example, metallic, couple the lower electrodes 105 of the visible photodetectors to the readout circuits formed inside and on top of semiconductor substrate 101.

As an example, lower organic level 401 is first deposited on the upper surface of interconnection stack 103. First openings are then formed in level 401 at the desired locations of vias 407. Then, dielectric layer 405 is deposited on lower organic level 401. During this step, dielectric layer 405 fills the first openings previously formed in level 401. Second openings, for example aligned with respect to the first openings, are then formed in dielectric layer 403. The second openings cross dielectric layer 405 and lower organic level 401 and expose portions of the upper surface of interconnection stack 103. Second openings for example have, in top view, lateral dimensions smaller than those of the first openings so that the edges of the second openings are coated with portions (not detailed in the drawing) of dielectric layer 405. Each second opening is then filled with a metal deposition to complete the forming of vias 407. The metal portion of each via 407 is electrically insulated from lower organic level 401 by the portions of dielectric layer 405 coating the sides of the second openings.

As in the previous examples, the visible photodetectors are laterally offset with respect to the infrared photodetectors. Further, microlenses 113 are laterally offset with respect to color filters 111.

This particularly enables to limit the occultation of the infrared photodetectors by the metallizations coupling the visible photodetectors to the interconnection stack 103 coating lower substrate 101.

In the embodiment of FIG. 4, each microlens 113 is a converging microlens adapted to focusing the incident light onto or into the active region of at least one underlying infrared photodetector. As an example, the focusing cone 115 of the light transmitted by each microlens 113 is flush with the metallizations the coupling underlying visible photodetectors to interconnection stack 103. The light may further or as a variant be focused according to cone 117 at a point of interconnection stack 103 located approximately vertically in line with the center of the underlying microlens 113.

It should be noted that the variants of FIGS. 2 and 3 may be adapted to the embodiment of FIG. 4.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A color and infrared image sensor comprising:
a first level having infrared photodetectors formed therein;
a second level, located above the first level, having visible photodetectors formed therein; and
a layer of microlenses comprising, for each infrared photodetector, a specific microlens arranged to focus the incident rays on the infrared photodetector,
wherein the visible photodetectors are laterally offset with respect to the infrared photodetectors.

2. The color and infrared image sensor according to claim 1, further comprising, between the second level and the layers of microlenses, a layer of color filters comprising a specific color filter in front of each visible photodetector.

3. The color and infrared image sensor according to claim 2, wherein the color filters are laterally separated from one another by opaque walls (201).

4. The color and infrared image sensor according to claim 2, wherein the microlenses are laterally offset with respect to the color filters.

5. The color and infrared image sensor according to claim 1, wherein the visible photodetectors are arranged in a first array, and the infrared photodetectors are arranged in a second array of same resolution and of same pitch as the first array.

6. The color and infrared image sensor according to claim 5, wherein, in top view, the center-to-center distance between any two neighboring visible and infrared photodetectors is substantially equal to half the pitch of the first and second arrays.

7. The color and infrared image sensor according to claim 1, further comprising an inorganic semiconductor substrate inside and on top of which are formed circuits for reading from the visible and infrared photodetectors.

8. The color and infrared image sensor according to claim 7, wherein the infrared photodetectors are inorganic photodetectors formed in said semiconductor substrate and the visible photodetectors are organic photodetectors.

9. The color and infrared image sensor according to claim 7, wherein the infrared photodetectors are organic photodetectors formed above the semiconductor substrate and the visible photodetectors are organic photodetectors.

10. The color and infrared image sensor according to claim 1, wherein each visible photodetector has an active region separated from active areas of the other photodetectors by an opaque wall.

11. The color and infrared image sensor according to claim 7, wherein the inorganic semiconductor substrate is made of single-crystal silicon.
